(19) United States
(12) Patent Application Publication
(10) Pub. No.: US 2025/0079858 A1
(43) Pub. Date: Mar. 6, 2025

(54) MULTIFUNCTIONAL STATION FOR NINTENDO SWITCH GAME CONSOLE

(71) Applicant: Guangzhou Zhongtianxin Electronic Technology Co.,Ltd, Guangzhou (CN)

(72) Inventor: Zheng LIU, Yiyang (CN)

(73) Assignee: Guangzhou Zhongtianxin Electronic Technology Co.,Ltd, Guangzhou (CN)

(21) Appl. No.: 18/512,393

(22) Filed: Nov. 17, 2023

(30) Foreign Application Priority Data
Aug. 28, 2023 (CN) 2023223239100

(51) Int. Cl. H02J 7/00; A63F 13/95; H01R 33/92; H05K 7/02

(52) U.S. Cl. CPC H02J 7/0044; A63F 13/95; H01R 33/92; H05K 7/02

(57) ABSTRACT

The present utility model discloses a multifunctional station for Nintendo Switch game console, comprising a base. The described base is equipped with a control circuit. The base is equipped with a console interface, a TV connection interface and a power interface. The console interface, the TV connection interface and the power interface are electrically connected to the control circuit respectively. The base is also equipped with Joy-Con controller charging slots and game card storage slots. The Joy-Con controller charging slots are provided with charging contacts. The control circuit is also electrically connected to the charging contacts inside the Joy-Con controller charging slots. The present utility model can simultaneously charge game controllers, store game cards, and display the game interface on a TV screen.

### CROSS-REFERENCE TO RELATED APPLICATIONS

The application claims priority to Chinese patent application No. 2023223239100, filed on Aug. 28, 2023, the entire contents of which are incorporated herein by reference.

### TECHNICAL FIELD

The present utility model relates to the technical field of a game console station, in particular to a multifunctional station for Nintendo Switch game console.

### BACKGROUND

The Nintendo Switch is a popular game console with a unique console station design that allows players to switch between portable mode and TV mode at any time. However, the current Nintendo Switch console station on the market usually has a single function, only connecting to the console and then projecting the console screen to the TV.

The existing Nintendo Switch console station does not charge the game controllers and does not have the ability to store game cards.

Therefore, the prior art needs to be improved.

### SUMMARY

In view of the shortcomings of the prior art, the present utility model aims to provide a multifunctional station for Nintendo Switch game console, which is designed to not only charge the game controller, store the game card, but also project the game interface to the TV.

To achieve the aforementioned objectives, the present utility model adopts the following technical solutions:

A multifunctional station for Nintendo switch game console, comprising a base. The described base is equipped with a control circuit. The base is equipped with a console interface, a TV connection interface and a power interface. The console interface, the TV connection interface and the power interface are electrically connected to the control circuit respectively, wherein:

The base is also equipped with Joy-Con controller charging slots and game card storage slots. The Joy-Con controller charging slots are provided with charging contacts. The control circuit is also electrically connected to the charging contacts inside the Joy-Con controller charging slots.

Wherein, the Joy-Con controller charging slots include slot body opened on the base, push-in entrances located at the edge of the base and connected with one end of the described slot body, and locating plates located at the other end of the slot body, the charging contacts are arranged inside the slot body.

Wherein, C-shaped clamps are installed inside the described slot body, the bottom walls of the C-shaped clamps are fixed on the bottom walls of the slot body, and the bottom walls of the C-shaped clamps are also provided with charging interfaces to expose the charging contacts.

Wherein, the game card storage slots are arranged on the upper surface of the base; the game card storage slots include rectangular clamp slots, pick-and-place notches are arranged at one end of the rectangular clamp slots and connected with the rectangular clamp slots.

Wherein, the rectangular clamp slots are equipped with elastic clamping strips on their side walls.

Wherein, the base includes a U-shaped clamping seat extending along one side wall for holding the console; the U-shaped clamping seat is provided with a console slot with an upper end opening; and the bottom wall of the console slot is provided with the console interface.

Wherein, the U-shaped clamping seat in the console slot is equipped with silicone clamp blocks on the side walls.

Wherein, the upper surface of the base is also equipped with status indicator lights connected to the control circuit.

Wherein, the side wall of the base is equipped with a switch electrically connected to the control circuit.

Wherein, the power interface is a Type-C interface, and the TV connection interface is an HDMI interface.

It should be understood that within the scope of the present utility model, the above technical features of the present utility model and the technical features described in the following (such as the embodiments) can be combined with each other, thereby constituting a new or preferred technical solution, limited by space, here will not be described one by one.

The beneficial effects of the present utility model are as follows: By setting the Joy-Con controller charging slot and game card storage slot on the base, the Joy-Con controller charging slot is provided with charging contacts, so that when Joy-Con controllers are placed in the Joy-Con controller charging slots, they can be charged. At the same time, the game card storage slot can store the game cards of the game console, to prevent them from being lost due to being scattered. The base is provided with a console interface and a TV connection interface. By connecting the game console to the base through the console interface, and then connecting the TV to the base through the TV connection interface, the interface of the game console can be transmitted to the TV for screen display. The present utility model has multiple functions of controller charging, game card storage and TV screen display with only one base, eliminating the need to purchase multiple accessories for a multifunctional experience, and enhancing the convenience and experience for players.

### BRIEF DESCRIPTION OF DRAWINGS

In order to illustrate the embodiments of the present utility model or technical solutions in the prior art more clearly, the drawings needed in the description of the embodiments or the prior art will be briefly introduced in the following. Obviously, the drawings in the following description are only some embodiments of the present utility model. For person skilled in the art, other drawings can be obtained based on the structures shown in these drawings, without putting in creative labor.

FIG. 1 is a schematic diagram of an embodiment of the multifunctional station for Nintendo Switch game console in the present utility model;

FIG. 2 is a schematic diagram of the circuit composition of the multifunctional station for Nintendo Switch game console in the present utility model;

FIG. 3 is a schematic diagram of the installation of the console, game controllers, and game cards in the structure shown in FIG. 1;

FIG. 4 is an exploded view of the structure shown in FIG. 3;

FIG. 5 is an exploded view of the structure shown in FIG. 1;

FIG. 6 is an enlarged schematic diagram of a partial structure shown in FIG. 5;

FIG. 7 is a schematic diagram of another perspective of the structure shown in FIG. 1.

Description of the Drawing Reference Signs:
100—Station, 1—Base, 2—Control Circuit, 3—Console Interface, 4—TV Connection Interface, 5—Power Interface, 6—Joy-Con Controller Charging Slot, 61—Slot Body, 62—Push-in Entrance, 63—Locating Plate, 7—Game Card Storage Slot, 71—Rectangular Clamp Slot, 72—Pick-and-Place Notch, 73—Elastic Clamping Strip, 8—Charging Contact, 9—C-shaped Clamp, 91—Charging Interface, 10—U-shaped Clamping Seat, 11—Console Slot, 12—Silicone Clamp Block, 13—Status Indicator Light, 14—Switch, 200—Console, 300—Joy-Con Controller, 400—Game Card.

### DETAILED DESCRIPTION OF THE EMBODIMENTS

In the following, the technical solution in the present utility model embodiment will be clearly and completely described in conjunction with the drawings in the present utility model embodiment. Obviously, the described implementation example is only a part of the present utility model and not the entirety of embodiments. Based on the embodiments in the present utility model, all other embodiments obtained by person skilled in the art without making creative labor shall fall within the scope of protection of the present utility model.

It should be noted that all directional indications (such as up, down, left, right, front, back . . . ) in the embodiments of the present utility model are only used to explain the relative positional relationship and movement of the various components under a specific posture (as shown in the drawings). If the specific posture changes, the directional indications will change accordingly.

In the present utility model, unless otherwise expressly specified and limited, the terms “connection” and “fixing” shall be interpreted in a broad sense. For example, “connection” may mean a fixed connection, a detachable connection, or integration; it can be a mechanical connection or an electrical connection; it can be a direct connection or an indirect connection through an intermediate medium; it can be an internal connection within two components or an interaction between two components, unless otherwise specified. For person skilled in the art, they can understand the specific meanings of the above terms in the present utility model based on the specific circumstances.

In addition, the description of “first”, “second”, etc., in the present utility model is only for the purpose of description and cannot be understood as indicating or implying its relative importance or implicitly indicating the number of technical features indicated. Thus, a feature that is defined as “first” or “second” may explicitly or implicitly include at least one such feature.

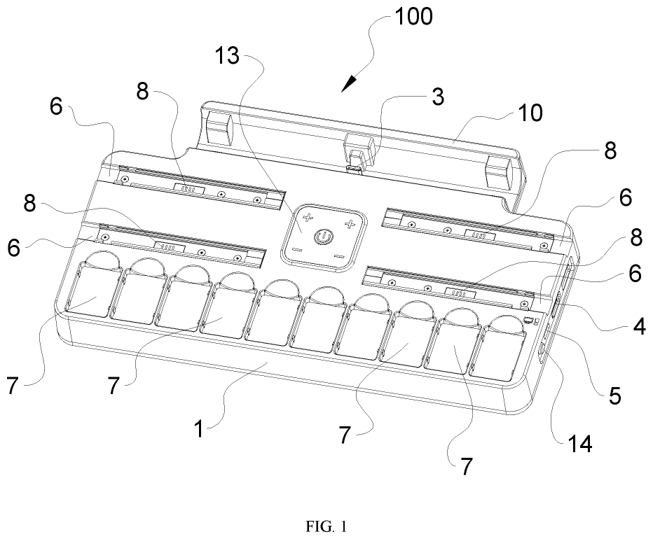

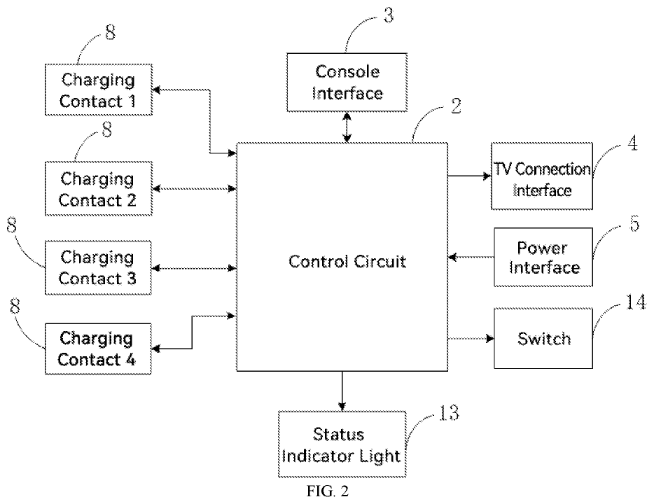

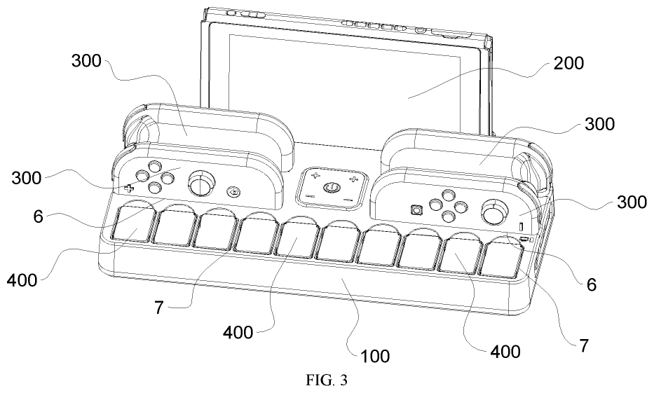

Please refer to FIG. 1 to FIG. 4. The present utility model proposes a multifunctional station 100 for Nintendo Switch game console, including a base 1. The base 1 is provided with a control circuit 2, the base 1 is provided with a console interface 3, a TV connection interface 4 and a power interface 5. The console interface 3, the TV connection interface 4 and the power interface 5 are electrically connected with the control circuit 2 respectively. The control circuit 2 of the embodiment can be provided on a PCB board. As shown in FIG. 3, when the console 200 of the game console is installed on the base 1, the console 200 is connected to the control circuit 2 of the station 100 through the console interface 3, and then connected to the TV through the TV connection interface 4. The control circuit 2 can process the image of the interface of the console 200 and output it to the TV from the TV connection interface 4 for screen display. Power interface 5 can supply power to control circuit 2. As an embodiment, the control circuit 2 of the embodiment can include an MCU module, an image processing module and a power management module. The MCU module, the image processing module and the power management module can use the existing circuit modules, and specific circuit diagrams are not shown here. The MCU module controls image output, charge and discharge management, etc. The image processing module processes the image of console 200 to adapt to play on the TV.

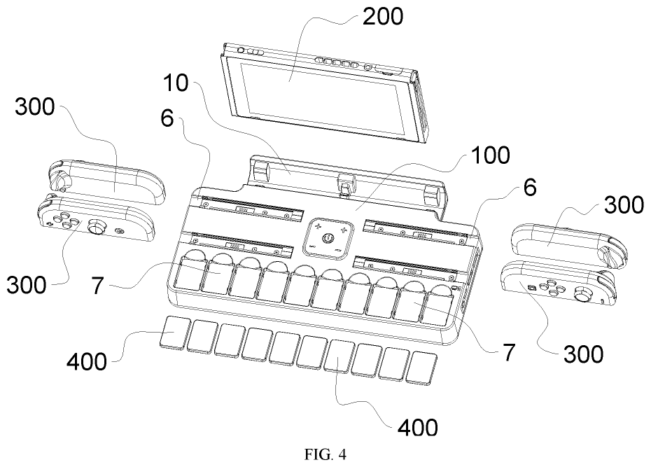

On the base 1 of the present utility model, there are also Joy-Con controller charging slots 6 and game card storage slots 7. The charging contacts 8 are arranged inside the Joy-Con controller charging slots 6, and the control circuit 2 is electrically connected to the charging contacts 8 inside the Joy-Con controller charging slots 6. The charging contacts 8 can include positive and negative terminals and feedback signal contacts, etc. As shown in FIGS. 3 and 4, the Joy-Con controller charging slots 6 are used to place Joy-Con controllers 300, and the game card storage slots 7 are used to place game cards 400. Since each Joy-Con controller charging slot 6 is equipped with charging contacts 8, when a Joy-Con controller 300 is placed in the Joy-Con controller charging slot 6, the charging contacts 8 will make contact with the charging pins of the Joy-Con controller 300. The control circuit 2 detects the connection of the charging circuit and activates the charging function for the Joy-Con controller 300. Once the charging is complete, the charging function is automatically disconnected.

Preferably, the base 1 of the present utility model is equipped with four Joy-Con controller charging slots 6, which means there are four sets of charging contacts 8 on the entire base 1. This allows for simultaneous charging of four Joy-Con controllers 300. The base 1 of the present utility model also has multiple game card storage slots 7, allowing for the simultaneous placement of multiple game cards 400.

As shown in FIGS. 3 and 4, the station 100 of the present utility model not only accommodates the console 200 but also integrates multiple functions such as game controller charging, game card storage, and TV screen display. This enhances the user convenience and gaming experience, as players do not need to purchase multiple accessories to enjoy the aforementioned multifunctional experience.

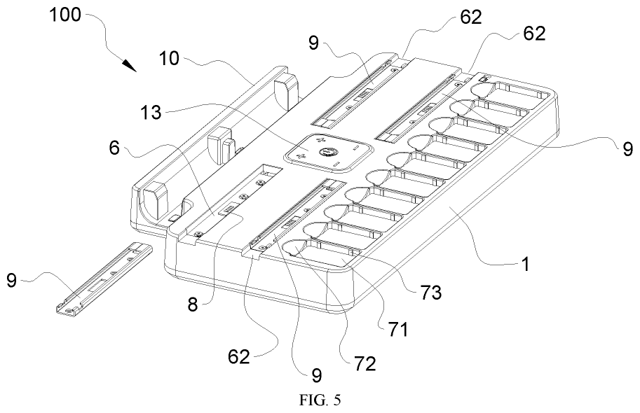

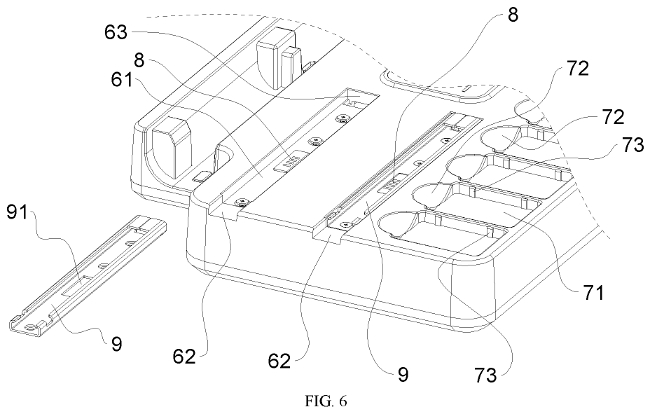

Specifically, as shown in FIGS. 5 and 6, the Joy-Con controller charging slots 6 include slot body 61 opened on the base 1, push-in entrances 62 located at the edge of the base 1 and connected with one end of the described slot body 61, and locating plates 63 located at the other end of the slot body 61, the charging contacts 8 are arranged inside the slot body 61. In the embodiment, the Joy-Con controller charging slot 6 is opened on the upper surface of the base 1, and the setting of the push-in entrance 62 facilitates the sliding installation of the Joy-Con controller 300 into the Joy-Con controller charging slot 6 from the side of the base 1, making it easier to install the Joy-Con controller 300. Meanwhile, the setting of the locating plate 63 prevents the Joy-Con controller 300 from sliding beyond the installation position, thereby ensuring that the charging contacts 8 are aligned with the charging pins on the Joy-Con controller 300.

Furthermore, a C-shaped clamp 9 is installed inside the slot body 61, with the bottom wall of the C-shaped clamp 9 fixed on the bottom wall of the slot body 61. The bottom wall of the C-shaped clamp 9) is also provided with a charging interface 91 to expose the charging contacts 8. The C-shaped clamp 9 has a guiding effect during the sliding-in process of the Joy-Con controller, and the top edges of the C-shaped clamp 9 are bent inward, providing a clamping and fixing effect on the Joy-Con controller 300. The bottom wall of the C-shaped clamp 9 can be secured to the bottom wall of the slot body 61 using screws.

The game card storage slot 7 of the embodiment is arranged on the upper surface of the base 1, and the game card storage slot 7 is separated from the Joy-Con controller charging slot 6.

The game card storage slots 7 include rectangular clamp slots 71, pick-and-place notches 72 are arranged at one end of the rectangular clamp slots 71 and connected with the rectangular clamp slots 71. The rectangular clamp slots 71 are used to hold and place the game cards 400, while the pick-and-place notches 72 facilitates the pick and place of the game cards 400.

Furthermore, as shown in FIG. 6, the side wall of the rectangular clamp slot 71 is also equipped with elastic clamping strips 73. This ensures a firm grip on the game cards 400 without damaging them.

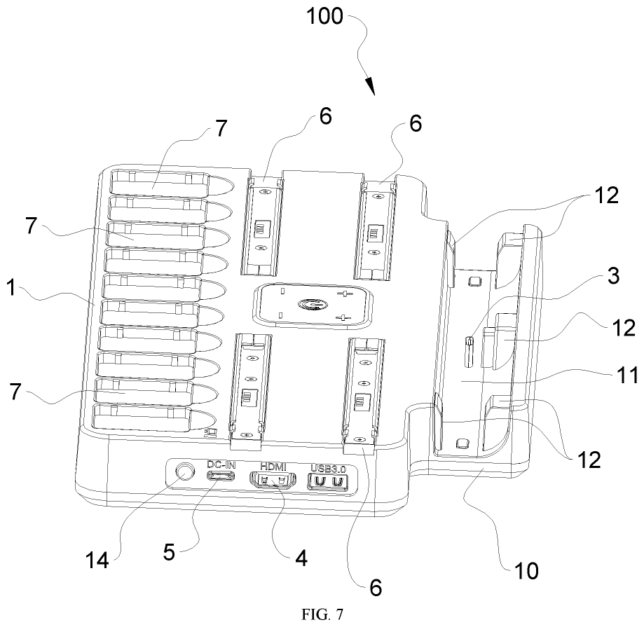

As shown in FIG. 7, the base 1 includes a U-shaped clamping seat 10 extending along one side wall for holding the console 200. The U-shaped clamping seat 10 is provided with a console slot 11 with an upper end opening. The bottom wall of the console slot 11 is provided with the console interface 3. In this way, when installing the console 200 on the base 1, the console 200 is placed on the upper end of the U-shaped clamping seat 10, aligning the console's interface with the console interface 3 inside the console slot 11, and then the console 200 is inserted downward to complete the installation and circuit connection of the console 200.

Furthermore, the U-shaped clamping seat 10 is equipped with silicone clamp blocks 12 on the side walls of the console slot 11. The silicone clamp blocks 12 securely hold the console 200 without causing damage.

Preferably, the upper surface of the base 1 is also equipped with a status indicator light 13 connected to the control circuit 2. The status indicator light 13 can display the charging status.

As shown in FIG. 7, the side wall of the base 1 is also equipped with a switch 14 connected to the control circuit 2. The switch 14 can control the power supply of the entire station 100, turning it on or off.

Preferably, the power interface 5 of the station 100 in the embodiment is a Type-C interface, and the TV connection interface 4 is an HDMI interface. The Type-C interface is easy to adapt to commonly used data cables, while the HDMI interface can output high-definition images to the TV.

The multifunctional station for Nintendo Switch game console in the present utility model is equipped with Joy-Con controller charging slots 6 and game card storage slots 7 on the base 1. The Joy-Con controller charging slot 6 is equipped with charging contacts 8, so when the Joy-Con controller 300 is inserted into the Joy-Con controller charging slot 6, it can be charged. At the same time, the game card storage slot 7 can place the game cards 400, preventing them from being misplaced. Additionally, the station 100 is equipped with a console interface 3 and a TV connection interface 4. By connecting the console 200 of the game console to the station 100 via the console interface 3, and then connecting the station 100 to the TV via the TV connection interface 4, the station 100 can transmit the game interface of the console 200 to the TV for screen display. The utility model incorporates multiple functions including controller charging, game card storage, and TV projection with just one station 100, eliminating the need to purchase multiple accessories to achieve a multifunctional experience. This greatly enhances user convenience and gaming experience.

The above description is only provided to illustrate the examples of the utility model and is not intended to limit the scope of the patent of the present utility model. It is not possible to exhaustively list all possible embodiments here. Any equivalent structural changes made using the content of the technical solution of the present utility model, or the direct/indirect application of this content to other related technical fields are all included in the patent protection scope of the present utility model.

What is claimed is:

1. A multifunctional station for Nintendo Switch game console, including a base; The base is provided with a console interface, a TV connection interface and a power interface; The console interface, the TV connection interface and the power interface are electrically connected to the control circuit respectively; The utility model is characterized in that;
The base is also provided with Joy-Con controller charging slots and game card storage slots; The Joy-Con controller charging slots are provided with charging contacts; The control circuit is also electrically connected to the charging contacts inside the Joy-Con controller charging slots.

2. The multifunctional station for Nintendo Switch game console, as described in claim 1 is characterized in that the Joy-Con controller charging slots include slot body opened on the base, push-in entrances located at the edge of the base and connected with one end of the described slot body, and locating plates located at the other end of the slot body, the charging contacts are arranged inside the slot body.

3. The multifunctional station for Nintendo Switch game console, as described in claim 2 is characterized in that C-shaped clamps are installed inside the described slot body, the bottom walls of the C-shaped clamps are fixed on the bottom walls of the slot body, and the bottom walls of the C-shaped clamps are also provided with charging interfaces to expose the charging contacts.

4. The multifunctional station for Nintendo Switch game console, as described in claim 1 is characterized in that the game card storage slots are arranged on the upper surface of the base; the game card storage slots include rectangular clamp slots, pick-and-place notches are arranged at one end of the rectangular clamp slots and connected with the rectangular clamp slots.

5. The multifunctional station for Nintendo Switch game console, as described in claim 4 is characterized in that the rectangular clamp slots are equipped with elastic clamping strips on their side walls.

6. The multifunctional station for Nintendo Switch game console, as described in claim 1 is characterized in that the base includes a U-shaped clamping seat extending along one side wall for holding the console; the U-shaped clamping seat is provided with a console slot with an upper end opening; and the bottom wall of the console slot is provided with the console interface.

7. The multifunctional station for Nintendo Switch game console, as described in claim 6 is characterized in that the U-shaped clamping seat in the console slot is equipped with silicone clamp blocks on the side walls.

8. The multifunctional station for Nintendo Switch game console, as described in claim 1 is characterized in that the upper surface of the base is also equipped with status indicator lights connected to the control circuit.

9. The multifunctional station for Nintendo Switch game console, as described in claim 1 is characterized in that the side wall of the base is equipped with a switch electrically connected to the control circuit.

10. The multifunctional station for Nintendo Switch game console, as described in claim 1 is characterized in that the power interface is a Type-C interface, and the TV connection interface is an HDMI interface.
